(19) United States
(12) Patent Application Publication
(10) Pub. No.: US 2009/0232928 A1
(43) Pub. Date: Sep. 17, 2009

(54) Method of Manufacturing Stamper, and Stamper

(75) Inventors: Shinobu Sugimura, Yokohama-shi (JP); Kaori Kimura, Tokyo (JP); Takuya Shimada, Yokohama-shi (JP); Yoshiyuki Kamata, Tokyo (JP); Masatoshi Sakurai, Tokyo (JP)

Correspondence Address: BLAKELY SOKOLOFF TAYLOR & ZAFMAN LLP, 1279 OAKMEAD PARKWAY, SUNNYVALE, CA, 94085-4040, US

(73) Assignee: KABUSHIKI KAISHA TOSHIBA, Tokyo (JP)

(21) Appl. No.: 12/473,071

(22) Filed: May 27, 2009

Related U.S. Application Data
(63) Continuation of application No. PCT/JP2008/066031, filed on Aug. 29, 2008.

(30) Foreign Application Priority Data
Sep. 28, 2007 (JP) 2007-256161

(51) Int. Cl. B29C 43/00; G03F 7/20

(52) U.S. Cl. 425/470; 430/320

(57) ABSTRACT

According to one embodiment, a method of manufacturing a stamper includes forming a conductive layer on a surface of a master having patterns of protrusions and recesses, forming an electroforming layer on the conductive layer, separating the electroforming layer and the conductive layer from the master to form a stamper to which the patterns of protrusions and recesses of the master are transferred, removing a resist left on the surface of the stamper, and etching the surface of the stamper with an acidic solution having a pH value of less than 3.

### CROSS-REFERENCE TO RELATED APPLICATIONS

This is a Continuation Application of PCT Application No. PCT/JP2008/066031, filed Aug. 29, 2008, which was published under PCT Article 21(2) in English.

This application is based upon and claims the benefit of priority from Japanese Patent Application No. 2007-256161, filed Sep. 28, 2007, the entire contents of which are incorporated herein by reference.

### BACKGROUND

1. Field

One embodiment of the present invention relates to a method of manufacturing a stamper used to produce a large number of information recording media by means of injection molding or imprinting technique to transfer patterns, and a stamper manufactured by the method.

2. Description of the Related Art

In manufacture of optical recording media represented by CDs (compact disks) and DVDs (digital versatile disks), a method is usually employed in which injection molding is carried out using a nickel (Ni) stamper having a thickness of about 300 μm as a mold.

With regard to magnetic recording, a read/write system using a discrete track recording (DTR) medium has been proposed to achieve high recording density (see Jpn. Pat. Appln. KOKAI Publication No. 2004-110896). In manufacture of the DTR media, a method is employed in which fine patterns of a nickel (Ni) stamper are transferred by nano-imprinting lithography.

The stamper is manufactured by, for example, the following methods. A resist is applied to a Si wafer or polished glass substrate, and then patterns are drawn on the resist by artificial method as follow. At this time, electron beam (EB) lithography or focused ion beam (FIB) lithography is employed as a fine processing technique to form patterns of protrusions and recesses of 100 nm or less. The resist is developed to produce a master having patterns of protrusions and recesses on the surface thereof. A metal conductive layer is deposited on the surface of the master by sputtering, vacuum evaporation or electroless plating. The conductive layer is used as a seed to form an electroforming layer made of Ni by electroforming. The electroforming layer and the conductive layer are separated from the master to provide a father stamper. The father stamper is washed to remove organic materials such as resist residues. The father stamper thus obtained may be used to produce media by transferring patterns.

Also, a mother stamper or a son stamper may be manufactured from the father stamper. This method may be carried out in the following manner. An oxidized layer serving as a releasing layer is formed on the surface of the father stamper by anodic oxidation or oxygen RIE (reactive ion etching) or oxygen plasma ashing. A conductive layer is formed on the releasing layer and an electroforming layer made of Ni is further formed on the conductive layer. The electroforming layer and the conductive layer are separated from the father stamper to replicate a mother stamper. An oxidized layer serving as a releasing layer is formed on the surface of the mother stamper. A conductive layer is formed on the releasing layer and an electroforming layer made of Ni is further formed on the conductive layer. The electroforming layer and the conductive layer are separated from the mother stamper to replicate a son stamper.

The mother stamper or the son stamper is subjected to processes such as back surface polishing and punching, and then is used to mass-produce media by transferring patterns.

An example of a method of manufacturing a DTR medium using the stamper manufactured in the above manner will be described with reference to FIGS. 4A to 4F.

As shown in FIG. 4A, a magnetic layer 51 is deposited on a substrate 50 and a resist 52 is applied to the surface of the magnetic layer 51. A releasing agent is applied to the surface of the stamper manufactured in the above manner. As shown in FIG. 4B, the patterned surface of the stamper 30 is made to face the resist 52 and the patterns of the stamper 30 are transferred to the resist by imprinting. Then, the stamper 30 is released to form resist patterns 52a. As shown in FIG. 4C, resist residues left in the recesses of the resist patterns 52a are removed by oxygen RIE (reactive ion etching). As shown in FIG. 4D, the magnetic layer 51 is etched using the resist patterns 52a as masks to form magnetic patterns 51a. As shown in FIG. 4E, the resist pattern is removed. As shown in FIG. 4F, a nonmagnetic material is filled in the recesses and a protective film 53 is formed on the protective film 53 to manufacture a DTR medium.

Now, in the above production method, such a phenomenon occurs that the recesses are widened in the step of removing resist residues and in the step of etching the magnetic layer using the resist patterns as masks because of side etching. This phenomenon will be described with reference to FIGS. 5A to 5D. When exact transfer is made by imprinting, the width a of the protrusions of the stamper 30 (FIG. 5A) is almost the same as the width b of the recesses of the resist patterns 52a (FIG. 3B). However, side etching takes place in the step of removing the resist residues, so that the width c of the recesses of the resist pattern 52a (FIG. 5C) is increased. Also, side etching takes place in the step of etching the magnetic layer 51 by using the resist patterns 52a as masks, so that the width d of the recesses of the magnetic patterns 51a (FIG. 5D) is increased.

Because the ratio of the recess to the protrusion varies in the manufacturing process, it is necessary to form the stamper 30 such that the width a of the protrusions is smaller in consideration of the finally required ratio of the recess to the protrusion (a=b<c<d).

A method of manufacturing a stamper has already been proposed in which only the width of the patterns can be corrected without changing the depth and height of the patterns (see Jpn. Pat. Appln. KOKAI Publication No. 4-351731). In this method, resist residues left on the surface of the stamper separated from the resist master are removed, and then the surface metal layer is etched to change the width of the patterns. In this document, there are described a method in which plasma etching is carried out using CF₄ gas and a wet etching method using a mixed solution of phosphoric acid, nitric acid and water in a ratio of 80 parts, 4 parts and 16 parts. However, specific etching conditions are not described and therefore the width of the patterns cannot be satisfactorily controlled. Also, if a usual etching method is used, good releasing property is not always provided in processed in FIG. 4B, where a releasing agent is applied to the surface of the stamper, imprinting is carried out and then the stamper is released.

### BRIEF DESCRIPTION OF THE SEVERAL VIEWS OF THE DRAWINGS

A general architecture that implements the various feature of the invention will now be described with reference to the drawings. The drawings and the associated descriptions are provided to illustrate embodiments of the invention and not to limit the scope of the invention.

FIGS. 1A to 1F are sectional views showing a method of manufacturing a father stamper according to an embodiment of the present invention.

FIGS. 2A to 2D are sectional views showing a method of manufacturing a mother stamper according to an embodiment of the present invention.

FIGS. 3A to 3E are sectional views showing a method of manufacturing a son stamper according to an embodiment of the present invention.

FIGS. 4A to 4F are sectional views showing a method of manufacturing a DTR medium according to an embodiment of the present invention.

FIGS. 5A to 5D are sectional views for describing such a phenomenon that the width of a recess is increased when a DTR medium is etched.

FIGS. 6A and 6B are sectional SEM images of the protrusions of a stamper before and after etching.

FIG. 7 is a plan view showing the region where the Ra of a stamper according to the present invention is measured.

FIG. 8 is a graph showing the relationship between the etching time and the amount of etching with the pH value of an aqueous acidic solution used as a parameter.

FIG. 9 is a graph showing Ra of a stamper before etching, after etching using an aqueous solution having a pH value of 1 or after etching using an aqueous acidic solution having a pH value of 2.

FIG. 10 is a perspective view showing a magnetic recording apparatus according to an embodiment of the present invention.

### DETAILED DESCRIPTION

Embodiments of the present invention will be described with reference to the drawings. Each drawing is a schematic view for better understanding of the invention and therefore, the structures differ from actual ones in shape, dimension, ratio and the like. However, the designs of these structures in these drawings may be properly modified in consideration of the following descriptions and known techniques.

In general, according to an aspect of the present invention, there is provided a method of manufacturing a stamper, comprising: forming a conductive layer on a surface of a master having patterns of protrusions and recesses; forming an electroforming layer on the conductive layer; separating the electroforming layer and the conductive layer from the master to form a stamper to which the patterns of protrusions and recesses of the master are transferred; removing a resist left on the surface of the stamper; and etching the surface of the stamper with an acidic solution having a pH value of less than 3.

According to another aspect of the present invention, there is provided a method of manufacturing a stamper, comprising: forming a first conductive layer on a surface of a master having patterns of protrusions and recesses; forming a first electroforming layer on the first conductive layer; separating the first electroforming layer and the first conductive layer from the master to form a father stamper to which the patterns of protrusions and recesses of the master are transferred; removing a resist left on the surface of the father stamper; forming a first releasing layer on the surface of the father stamper; forming a second conductive layer on the first releasing layer; forming a second electroforming layer on the second conductive layer; separating the second electroforming layer and the second conductive layer from the father stamper to form a mother stamper to which the patterns of protrusions and recesses of the father stamper are transferred; forming a second releasing layer on the surface of the mother stamper; forming a third conductive layer on the second releasing layer; forming a third electroforming layer on the third conductive layer; separating the third electroforming layer and the third conductive layer from the mother stamper to form a son stamper to which the patterns of protrusions and recesses of the mother stamper are transferred; and etching the surface of the son stamper with an acidic solution having a pH value of less than 3.

According to still another aspect of the present invention, there is provided a stamper comprising patterns of protrusions and recessed on a surface thereof, wherein arithmetic average roughness Ra of the surface is 1 nm or more and 5 nm or less.

### Example 1

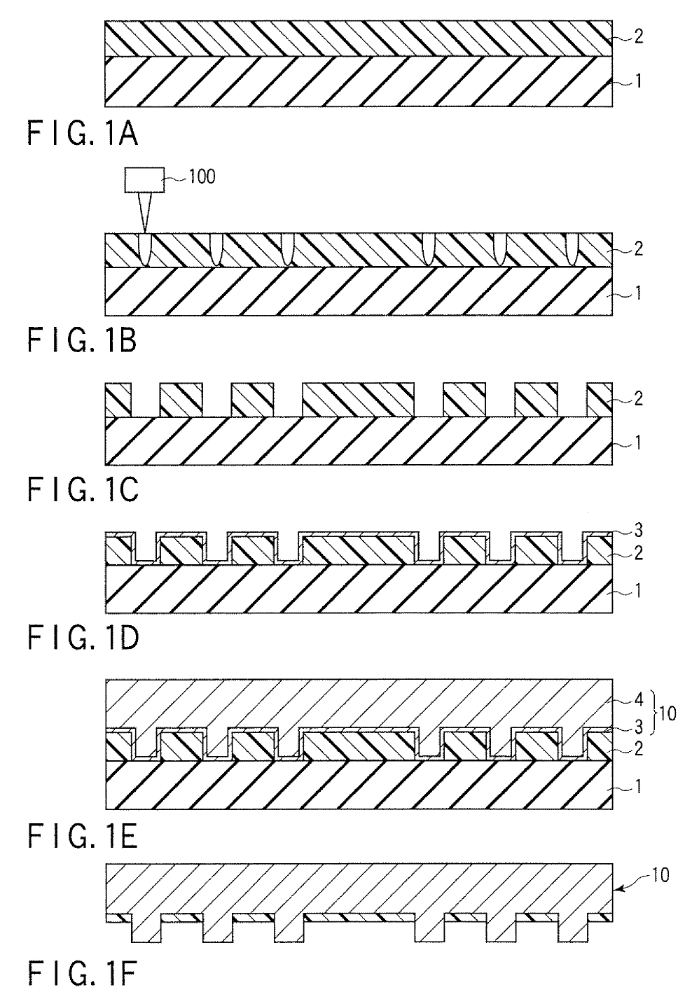

A method of manufacturing a replicated stamper according to an embodiment of the present invention will be described with reference to sectional views shown in FIGS. 1A to 1F, FIGS. 2A to 2D and FIGS. 3A to 3E.

As shown in FIG. 1A, a resist is applied to a substrate 1 used as a master by spin-coating and solvent components are vaporized by baking to cure the resist, thereby forming a resist layer 2. As shown in FIG. 1B, an electron beam (EB) direct writing system 100 is used to form patterns corresponding to tracks having a track pitch of 190 nm on the resist layer 2. When circular patterns are drawn on the surface of a disk substrate, a direct writing system with a turntable is usually used. In order to eliminate patterning deviation caused by rotation of the turntable, the master should be set to the turntable under such a condition of less eccentricity with respect to the turntable. The patterns are drawn on the central region of the master. As shown in FIG. 1C, the resist layer 2 is developed to form resist patterns 4a. In this embodiment, a positive type resist is used in which the drawn portions are made recesses. However, a negative type resist may be used in which the drawn portions are made protrusions. As shown in FIG. 1D, the patterned surface of the resist master is coated with a first conductive layer 3 made of Ni by sputtering or the like. As shown in FIG. 1E, the resist master is dipped in a nickel sulfamate solution and electroforming is carried out to form a first electroforming layer 4 on the first conductive layer 3 of the resist master. As shown in FIG. 1F, vacuum breaking is carried out from the edge of the resist master to separate a father stamper 10 in which the first electroforming layer 4 is integrated with the first conductive layer 3 from the resist master. At this time, resist residues are stuck to the father stamper 10.

The reason why the pitch of the patterns corresponding to the tracks is designed to be 200 nm or less as mentioned above is as follows. Specifically, a density of 60 GB (gigabyte) or more per 1.8-inch disk which is obtained by the current technologies is required in consideration of a recording density specific to a DTR medium. The recording track pitch at this time is about 200 nm and the DTR medium is desired to have a pitch less than the above pitch.

Also, in the resist master, the ratio of the width of the protrusions corresponding to the tracks to the width of the recesses corresponding to the separating portions between the tracks is desired to be larger than 2:1. Specifically, the width of the recesses is desired to be smaller than about 60 nm. In order to carry out such a fine processing, a method superior in controllability like that of the present invention is preferably used. In the case of an optical recording medium, the tracks take a form of lands/grooves or pit trains.

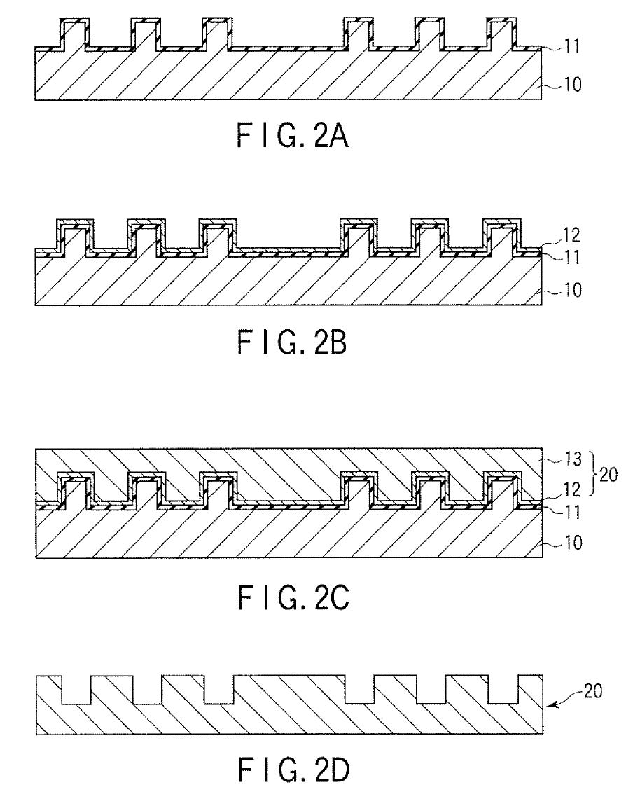

As shown in FIG. 2A, resist residues stuck to the father stamper 10 are removed by ashing with oxygen RIE (reactive ion etching) to expose the patterned surface of the father stamper 10, and then an oxidized layer 11 as a first releasing layer is formed on the patterned surface of the father stamper 10. As shown in FIG. 2B, a second conductive layer 12 is formed on the oxidized layer 11 formed on the patterned surface of the father stamper 10. As shown in FIG. 2C, a second electroforming layer 13 is formed by electroforming. As shown in FIG. 2D, vacuum breaking is carried out from the edge of the father stamper 10 to provide the father stamper 10 and a mother stamper 20 in which the second electroforming layer 13 is integrated with the second conductive layer 12.

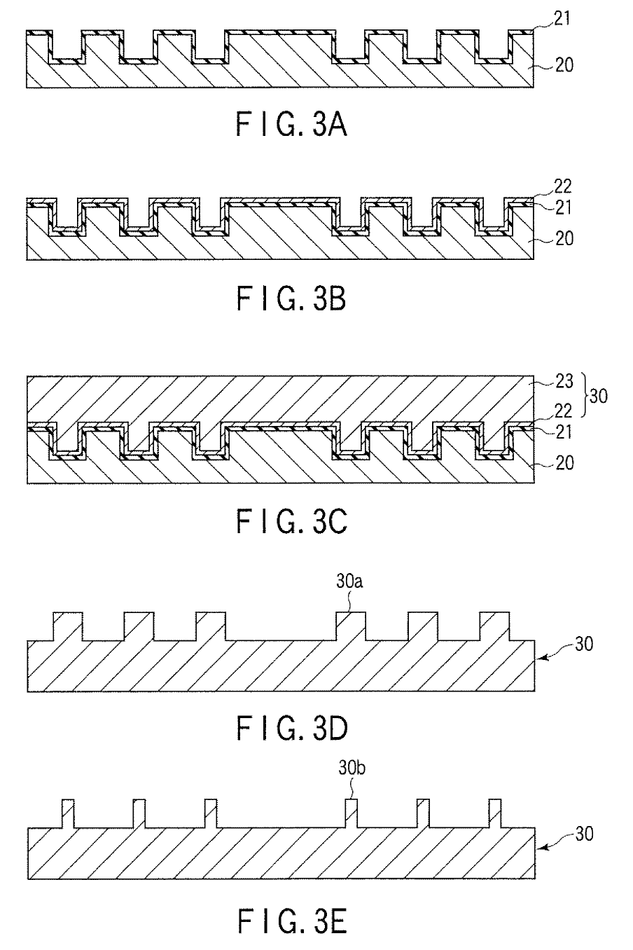

As shown in FIG. 3A, an oxidized layer 21 as a second releasing layer is formed on the patterned surface of the mother stamper 20. As shown in FIG. 3B, a third conductive layer 22 is formed on the oxidized layer 21 formed on the patterned surface of the mother stamper 20. As shown in FIG. 3C, a third electroforming layer 23 is formed by electroforming. As shown in FIG. 3D, vacuum breaking is carried out from the edge of the mother stamper 20 to obtain the mother stamper 20 and a son stamper 30 in which the third electroforming layer 23 is integrated with the third conductive layer 22. Protrusions 30a are formed on the son stamper 30. As shown in FIG. 3E, the son stamper 30 is immersed for 120 minutes in an aqueous sulfamic acid solution prepared by dissolving sulfamic acid in pure water and having a pH value adjusted to 2.0 and then washed with pure water. As a result, protrusions 30b reduced in width are formed.

Although not shown, a protective film is formed on the patterned surface by spin coating, followed by drying, and back surface polishing and punching, if desired. Thus, the son stamper having a final form can be provided.

Although the son stamper is etched in the present embodiment, the father stamper may be etched to produce a father stamper reduced in the width of the protrusions.

As the first, second and third conductive layers 3, 12 and 22, a metal containing Ni as its major component is generally used because it has high physical and mechanical strength and strong resistance to corrosion and abrasion and also in consideration of miscibility with Ni of the electroforming material. As the electroforming material, Ni or a metal including Ni and Co, S, B or P is generally used.

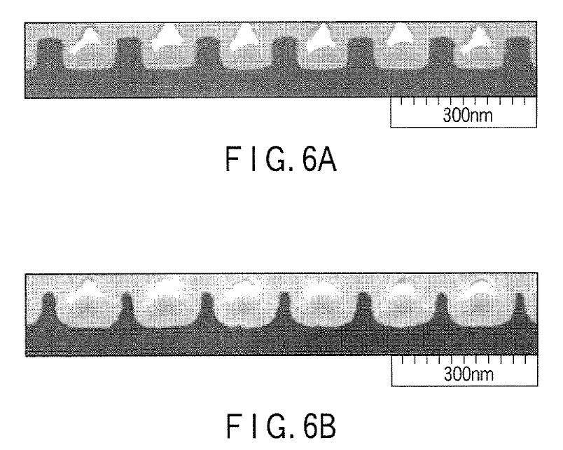

FIGS. 6A and 6B show the sectional SEM (scanning electron microscope) images of the patterned region of the son stamper manufactured by the method of this embodiment before and after etching. The width of the protrusions after etching as shown in FIG. 6B is smaller than the width of the protrusions before etching as shown in FIG. 6A. Specifically, the half value width of the protrusions shown in FIG. 6B is more reduced by 31 nm than that shown in FIG. 6A and the height of the protrusions shown in FIG. 6B is more increased by 7 nm than that shown in FIG. 6A. It is found from the result that the amount of etching is half of the reduction in half value width, namely, 15.5 nm.

Also, the sectional shape of the protrusions is rectangular before etching as shown in FIG. 6A, whereas it has a mountain shape with footing after etching as shown in FIG. 6B. This is because the son stamper is immersed in a static bath. In other words, the pH value of the aqueous sulfamic acid solution used to etch the stamper is raised when Ni is dissolved therein. It is considered that, because the liquid flow is hindered particularly in the recesses of the patterns, sulfamic acid having increased pH value is retained in the recesses, which retards etching.

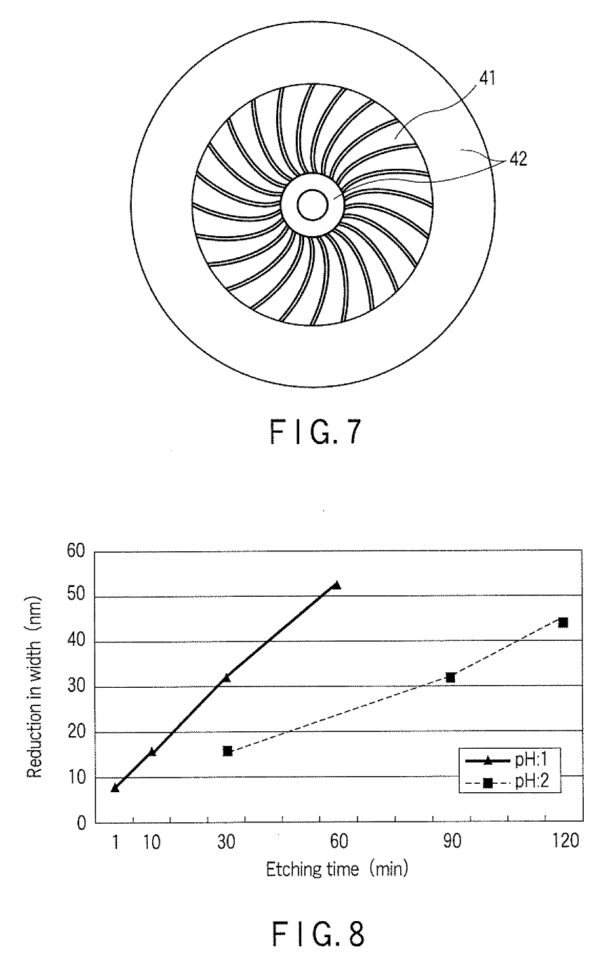

Further, an atomic force microscope (AFM) is used to measure the surface roughness (arithmetic average roughness Ra) of the stamper before and after etching. At this time, a scan area of 2 μm×2 μm square to be measured is set in a mirror area (non-pattern region) 42 in the outer or inner periphery other than the patterned region 41 of the stamper 30 shown in FIG. 7. This is because the surface roughness cannot be measured in a wide scan area in the patterned region 41 and therefore, a significant Ra cannot be obtained. As a result, Ra before etching is 0.9 nm whereas Ra after etching is 3.6 nm.

### Example 2

When an aqueous sulfamic acid solution having a pH value adjusted to 1.0 is used in the etching, it takes 30 minutes to etch the surface the son stamper by 15 nm which is almost the same as in Example 1. In this case, Ra of the stamper after etching is 4.2 nm. Here, in order to raise the concentration of sulfamic acid in pure water to adjust the etching solution to a higher pH value than that in Example 1, sulfamic acid is additionally dissolved while monitoring the pH value of the solution by means of a pH meter.

### Comparative Example 1

When an aqueous sulfamic acid solution having a pH value adjusted to 3.0 is used in the etching, neither reduction in pattern width nor increase in Ra is observed even after 120 minutes. Here, in order to lower the concentration of sulfamic acid in pure water to adjust the etching solution to a lower pH value than that in Example 1, pure water is added while monitoring the pH value of the solution by means of a pH meter.

From the above result, it is unpractical to carry out etching carried using an aqueous acidic solution having a pH value of 3.0 or more because a long time is required for etching, and it is therefore desired to carry out etching using an aqueous acidic solution having a pH value of less than 3.0.

FIG. 8 shows the relationship between the etching time and the amount of etching with the pH value of an aqueous acidic solution used as a parameter. As shown in FIG. 8, the amount of etching is almost directly proportional to the etching time.

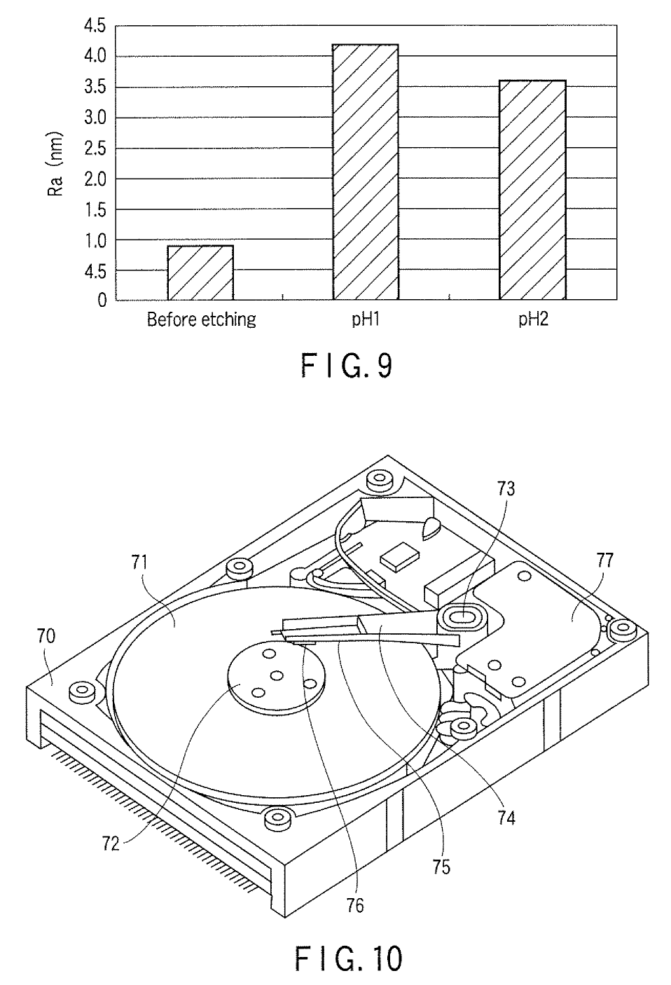

FIG. 9 shows Ra of the stamper before etching, after etching using an aqueous acidic solution having a pH value of 1 and after etching using an aqueous acidic solution having a pH value of 2. As shown in FIG. 9, Ra after etching varies with the pH value of an etching solution to be used and Ra is small when the pH value is high.

From these results, if the width of the protrusions formed on the stamper before etching is measured in advance, the amount of etching and Ra are properly controlled by adjusting the pH value and etching time, making it possible to obtain a stamper provided with protrusions having a desired width.

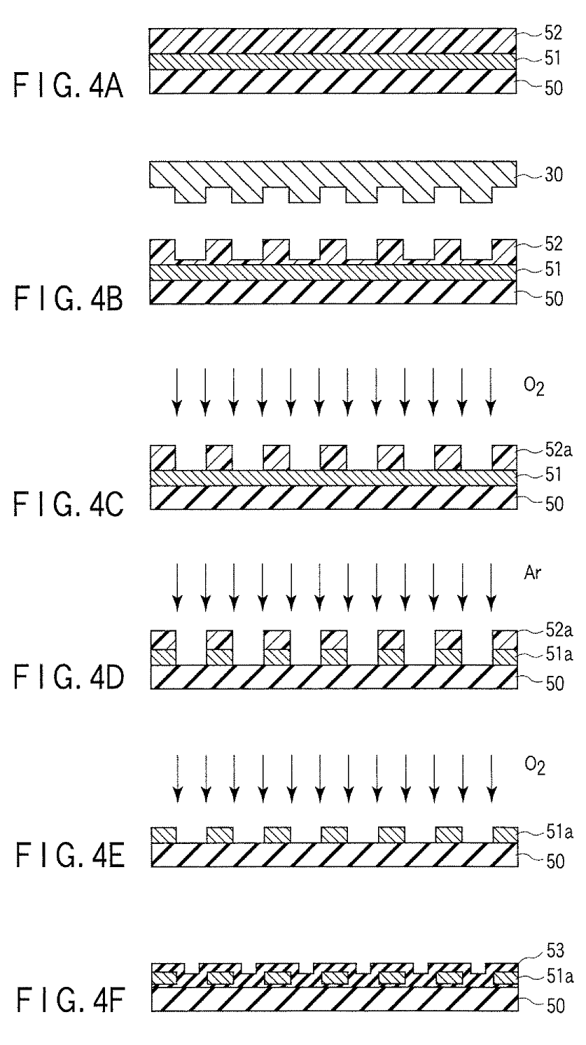

Next, using the stamper manufactured in Examples 1 and 2, DTR media are manufactured by a method as shown in FIGS. 4A to 4F. At this time, a releasing agent is applied to the surface of the stamper 30, patterns are transferred to the resist 52 by imprinting, and then the stamper 30 can be released satisfactorily in the step shown in FIG. 4B. This is considered to be due to such an effect that the releasing agent is improved in the affinity to the stamper because Ra of the surface of the stamper is increased.

Also, the obtained DTR medium is used to fabricate a magnetic recording apparatus (hard disk drive) as shown in FIG. 10. The magnetic recording apparatus is provided, in a chassis 70, with the above magnetic recording medium (DTR medium) 71, a spindle motor 72 that rotates the magnetic recording medium 71, a head slider 76 with a magnetic head incorporated therein, a head suspension assembly including a suspension 75 and an actuator arm 74 for supporting the head slider 76, and a voice coil motor (VCM) 77 as an actuator of the head suspension assembly.

The magnetic recording medium 71 is rotated by the spindle motor 72. A magnetic head containing a write head and a read head is incorporated into the head slider 76. The actuator arm 74 is rotatably attached to a pivot 73. The suspension 75 is attached to one end of the actuator arm 74. The head slider 76 is elastically supported via a gimbal incorporated into the suspension 75. The voice coil motor (VCM) 77 is disposed on the other end of the actuator arm 74. The voice coil motor (VCM) 77 generates a torque to the actuator arm 74 around the pivot 73 to control the position of the magnetic head such that the magnetic head is floated above an arbitrary radial position of the magnetic recording medium 71.

When the fabricated magnetic recording apparatus is evaluated, the error rate is improved.

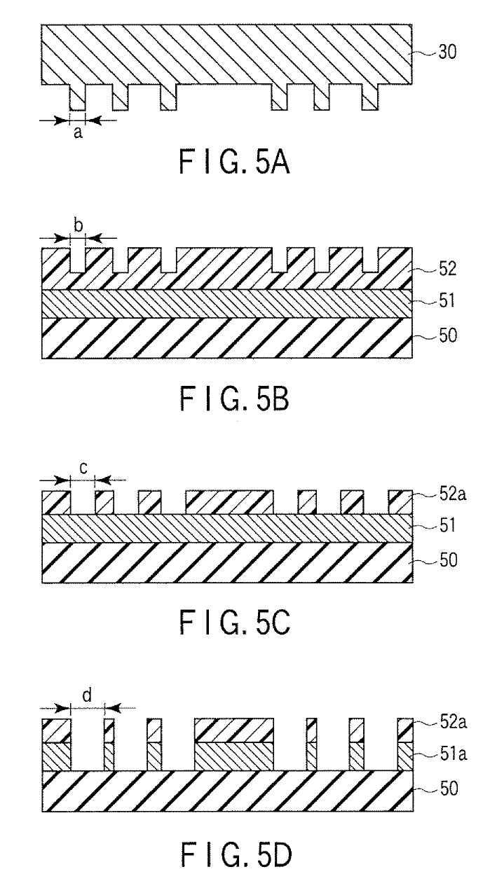

This is because the width a of the protrusions of the stamper shown in FIG. 5A is decreased and the width d of the recesses shown in FIG. 5D is decreased with the result that the width of the magnetic patterns 51a is increased.

Although the embodiments of the invention have been described, the present invention is not limited to the above embodiments and may be variously modified within the scope of the invention described in the claims. Also, various modifications can be made without departing from the spirit of the present invention when the invention is practiced. Also, various inventions may be made by combining plural structural elements disclosed in the above embodiments.

While certain embodiments of the inventions have been described, these embodiments have been presented by way of example only, and are not intended to limit the scope of the inventions. Indeed, the novel methods and systems described herein may be embodied in a variety of other forms; furthermore, various omissions, substitutions and changes in the form of the methods and systems described herein may be made without departing from the spirit of the inventions. The accompanying claims and their equivalents are intended to cover such forms or modifications as would fall within the scope and spirit of the inventions.

What is claimed is:

1. A method of manufacturing a stamper, comprising:
forming a conductive layer on a surface of a master having patterns of protrusions and recesses;
forming an electroforming layer on the conductive layer;
separating the electroforming layer and the conductive layer from the master to form a stamper to which the patterns of protrusions and recesses of the master are transferred;
removing a resist left on the surface of the stamper; and
etching the surface of the stamper with an acidic solution having a pH value of less than 3.

2. The method of claim 1, wherein a sulfamic acid solution is used as the acidic solution.

3. A method of manufacturing a stamper, comprising:
forming a first conductive layer on a surface of a master having patterns of protrusions and recesses;
forming a first electroforming layer on the first conductive layer;
separating the first electroforming layer and the first conductive layer from the master to form a father stamper to which the patterns of protrusions and recesses of the master are transferred;
removing a resist left on the surface of the father stamper;
forming a first releasing layer on the surface of the father stamper;
forming a second conductive layer on the first releasing layer;
forming a second electroforming layer on the second conductive layer;
separating the second electroforming layer and the second conductive layer from the father stamper to form a mother stamper to which the patterns of protrusions and recesses of the father stamper are transferred;
forming a second releasing layer on the surface of the mother stamper;
forming a third conductive layer on the second releasing layer;
forming a third electroforming layer on the third conductive layer;
separating the third electroforming layer and the third conductive layer from the mother stamper to form a son stamper to which the patterns of protrusions and recesses of the mother stamper are transferred; and
etching the surface of the son stamper with an acidic solution having a pH value of less than 3.

4. The method of claim 3, wherein a sulfamic acid solution is used as the acidic solution.

5. A stamper comprising patterns of protrusions and recessed on a surface thereof, wherein arithmetic average roughness Ra of the surface is 1 nm or more and 5 nm or less.

6. The stamper of claim 5, wherein a pitch of patterns corresponding to tracks used to record information is 200 nm or less.
